(19) United States
(12) Patent Application Publication
(10) Pub. No.: US 2008/0305598 A1
(43) Pub. Date: Dec. 11, 2008

(54) ION IMPLANTATION DEVICE AND A METHOD OF SEMICONDUCTOR MANUFACTURING BY THE IMPLANTATION OF IONS DERIVED FROM CARBORANE MOLECULAR SPECIES

(76) Inventors: Thomas N. Horsky, Boxborough, MA (US); Dale C. Jacobson, Salem, NH (US)

Correspondence Address: KATTEN MUCHIN ROSENMAN LLP;(C/O PATENT ADMINISTRATOR), 2900 K STREET NW, SUITE 200, WASHINGTON, DC, 20007-5118, US

(21) Appl. No.: 11/759,768

(22) Filed: Jun. 7, 2007

(51) Int. Cl. H01L 21/26; H01L 21/336

(52) U.S. Cl. 438/303; 438/513; 257/E21.328; 257/E21.409

(57) ABSTRACT

An ion implantation device and a method of manufacturing a semiconductor device is described, wherein ionized carborane cluster ions are implanted into semiconductor substrates to perform doping of the substrate. The carborane cluster ions have the chemical form C₂B₁₀Hₓ⁺, C₂B₈Hₓ⁺ and C₄B₁₈Hₓ⁺and are formed from carborane cluster molecules of the form C₂B₁₀H₁₂ ,C₂B₈H₁₀ and C₄B₁₈H₂₂ The use of such carborane molecular clusters results in higher doping concentrations at lower implant energy to provide high dose low energy implants. In accordance with one aspect of the invention, the carborane cluster molecules may be ionized by direct electron impact ionization or by way of a plasma.

### BACKGROUND OF THE INVENTION

1. Field of the Invention

The present invention relates to a method of semiconductor manufacturing in which P-type doping is accomplished by the implantation of ion beams formed from ionizing carborane molecules, e.g., C₂B₁₀H₁₂, C₂B₈H₁₀ and C₄B₁₈H₂₂,by direct impact and by arc discharge.

2. Description of the Prior Art

The Ion Implantation Process

The fabrication of semiconductor devices involves, in part, the introduction of impurities into the semiconductor substrate to form doped regions. The impurity elements are selected to bond appropriately with the semiconductor material so as to create electrical carriers, thus altering the electrical conductivity of the semiconductor material. The electrical carriers can either be electrons (generated by N-type dopants) or holes (generated by P-type dopants). The concentration of dopant impurities so introduced determines the electrical conductivity of the resultant region. Many such N- and P-type impurity regions must be created to form transistor structures, isolation structures and other such electronic structures, which function collectively as a semiconductor device.

The conventional method of introducing dopants into a semiconductor substrate is by ion implantation. In ion implantation, a feed material containing the desired element is introduced into an ion source and energy is introduced to ionize the feed material, creating ions which contain the dopant element (for example, in silicon the elements ⁷⁵As, ³¹P, and ¹²¹ Sb are donors or N-type dopants, while ¹¹B and ¹¹⁵In are acceptors or P-type dopants). An accelerating electric field is provided to extract and accelerate the typically positively-charged ions, thus creating an ion beam (in certain cases, negatively-charged ions may be used instead). Then, mass analysis is used to select the species to be implanted, as is known in the art, and the mass-analyzed ion beam may subsequently pass through ion optics which alter its final velocity or change its spatial distribution prior to being directed into a semiconductor substrate or workpiece. The accelerated ions possess a well-defined kinetic energy which allows the ions to penetrate the target to a well-defined, predetermined depth at each energy value. Both the energy and mass of the ions determine their depth of penetration into the target, with higher energy and/or lower mass ions allowing deeper penetration into the target due to their greater velocity. The ion implantation system is constructed to carefully control the critical variables in the implantation process, such as the ion energy, ion mass, ion beam current (electrical charge per unit time), and ion dose at the target (total number of ions per unit area that penetrate into the target). Further, beam angular divergence (the variation in the angles at which the ions strike the substrate) and beam spatial uniformity and extent must also be controlled in order to preserve semiconductor device yields.

A key process of semiconductor manufacturing is the creation of P—N junctions within the semiconductor substrate. This requires the formation of adjacent regions of P-type and N-type doping. An important example of the formation of such a junction is the implantation of P-type dopant into a semiconductor region already containing a uniform distribution of N-type dopant. In this case, an important parameter is the junction depth, which is defined as the depth from the semiconductor surface at which the P-type and N-type dopants have equal concentrations. This junction depth is a function of the implanted dopant mass, energy and dose.

An important aspect of modern semiconductor technology is the continuous evolution to smaller and faster devices. This process is called scaling. Scaling is driven by continuous advances in lithographic process methods, allowing the definition of smaller and smaller features in the semiconductor substrate which contains the integrated circuits. A generally accepted scaling theory has been developed to guide chip manufacturers in the appropriate resize of all aspects of the semiconductor device design at the same time, i.e., at each technology or scaling node. The greatest impact of scaling on ion implantation process is the scaling of junction depths, which requires increasingly shallow junctions as the device dimensions are decreased. This requirement for increasingly shallow junctions as integrated circuit technology scales translates into the following requirement: ion implantation energies must be reduced with each scaling step. The extremely shallow junctions called for by modern, sub-0.13 micron devices are termed “Ultra-Shallow Junctions”, or USJ.

### Physical Limitations on Low-Energy Beam Transport

Due to the aggressive scaling of junction depths in CMOS processing, the ion energy required for many critical implants has decreased to the point that conventional ion implantation systems, originally developed to generate much higher energy beams, deliver much reduced ion currents to the wafer, reducing wafer throughput. The limitations of conventional ion implantation systems at low beam energy are most evident in the extraction of ions from the ion source, and their subsequent transport through the implanter's beam line. Ion extraction is governed by the Child-Langmuir relation, which states that the extracted beam current density is proportional to the extraction voltage (i.e., beam energy at extraction) raised to the 3/2 power In a conventional ion implanter this regime of “extraction-limited” operation is seen at energies less than about 10 keV. Similar constraints affect the transport of the low-energy beam after extraction. A lower energy ion beam travels with a smaller velocity, hence for a given value of beam current the ions are closer together, i.e., the ion density increases. This can be seen from the relation J=ηev, where J is the ion beam current density in mA/cm², η is the ion density in ions/cm⁻³, e is the electronic charge (=6.02×10⁻¹⁹ Coulombs), and v is the average ion velocity in cm/s. In addition, since the electrostatic forces between ions are inversely proportional to the square of the distance between them, electrostatic repulsion is much stronger at low energy, resulting in increased dispersion of the ion beam. This phenomenon is called “beam blow-up”, and is the principal cause of beam loss in low-energy transport. While low-energy electrons present in the implanter beam line tend to be trapped by the positively-charged ion beam, compensating for space-charge blow-up during transport, blow-up nevertheless still occurs, and is most pronounced in the presence of electrostatic focusing lenses, which tend to strip the loosely-bound, highly mobile compensating electrons from the beam. In particular, severe extraction and transport difficulties exist for light ions, such as the P-type dopant boron, whose mass is only 11 amu. Being light, boron atoms penetrate further into the substrate than other atoms, hence the required implantation energies for boron are lower than for the other implant species. In fact, extremely low implantation energies of less than 1 keV are being required for certain leading edge USJ processes. In reality, most of the ions extracted and transported from a typical BF₃ source plasma are not the desired ion ¹¹B⁺, but rather ion fragments such as ¹⁹F⁺ and ⁴⁹BF₂⁺; these serve to increase the charge density and average mass of the extracted ion beam, further increasing space-charge blow-up. For a given beam energy, increased mass results in a greater beam perveance; since heavier ions move more slowly, the ion density η increases for a given beam current, increasing space charge effects in accordance with the discussion above. Similarly N-type dopant dimers and trimers such as As₂, As₃, P₂, and P₃ have been used to obtain lower energies of these dopant species.

### Molecular Ion Implantation

One way to overcome the limitations imposed by the Child-Langmuir relation discussed above is to increase the transport energy of the dopant ion by ionizing a molecule containing the dopant of interest, rather than a single dopant atom. In this way, while the kinetic energy of the molecule is higher during transport, upon entering the substrate, the molecule breaks up into its constituent atoms, sharing the energy of the molecule among the individual atoms according to their distribution in mass, so that the dopant atom's implantation energy is much lower than the original transport kinetic energy of the molecular ion. Consider the dopant atom “X” bound to a radical “Y” (disregarding for purposes of discussion the issue of whether “Y” affects the device-forming process). If the ion XY⁺ were implanted in lieu of X⁺, then XY⁺ must be extracted and transported at a higher energy, increased by a factor equal to the mass of XY divided by the mass of X; this ensures that the velocity of X in either case is the same. Since the space-charge effects described by the Child-Langmuir relation discussed above are super-linear with respect to ion energy, the maximum transportable ion current is increased. Historically, the use of polyatomic molecules to ameliorate the problems of low energy implantation is well known in the art. A common example has been the use of the BF₂⁺ molecular ion for the implantation of low-energy boron, in lieu of B⁺. This process dissociates BF₃ feed gas to the BF₂⁺ion for implantation. In this way, the ion mass is increased to 49 AMU, allowing an increase of the extraction and transport energy by more than a factor of 4 (i.e., 49/11) over using single boron atoms. Upon implantation, however, the boron energy is reduced by the same factor of (49/11). It is worthy of note that this approach does not reduce the current density in the beam, since there is only one boron atom per unit charge in the beam. In addition, this process also implants fluorine atoms into the semiconductor substrate along with the boron, an undesirable feature of this technique since fluorine has been known to exhibit adverse effects on the semiconductor device.

### Cluster Implantation

In principle, a more effective way to increase dose rate than by the XY⁺ model discussed above is to implant clusters of dopant atoms, that is, molecular ions of the form XₙYₘ⁺, where n and m are integers and n is greater than one. Recently, there has been seminal work using decaborane as a feed material for ion implantation. The implanted particle was a positive ion of the decaborane molecule, B₁₀H₁₄, which contains 10 boron atoms, and is therefore a “cluster” of boron atoms. This technique not only increases the mass of the ion and hence the transport ion energy, but for a given ion current, it substantially increases the implanted dose rate, since the decaborane ion B₁₀Hₓ⁺ has ten boron atoms. Importantly, by significantly reducing the electrical current carried in the ion beam (by a factor of 10 in the case of decaborane ions) not only are beam space-charge effects reduced, increasing beam transmission, but wafer charging effects are reduced as well. Since positive ion bombardment is known to reduce device yields by charging the wafer, particularly damaging sensitive gate isolation, such a reduction in electrical current through the use of cluster ion beams is very attractive for USJ device manufacturing, which must increasingly accommodate thinner gate oxides and exceedingly low gate threshold voltages. Thus, there is a critical need to solve two distinct problems facing the semiconductor manufacturing industry today: wafer charging, and low productivity in low-energy ion implantation. Even larger molecules have recently been used for p-type ion implantation. For example the B₁₈Hₓ⁺ ion, using the solid feed material octadecaborane, or B₁₈H₂₂ has been shown to provide an excellent pathway to ultra low energy ion implantation.

### Ion Implantation Systems

Ion implanters have historically been segmented into three basic categories: high current, medium current, and high energy implanters. Cluster beams are useful for high current and medium current implantation processes. In particular, today's high current implanters are primarily used to form the low energy, high dose regions of the transistor such as drain structures and doping of the polysilicon gates. They are typically batch implanters, i.e., processing many wafers mounted on a spinning disk, the ion beam remaining stationary. High current transport systems tend to be simpler than medium current transport systems, and incorporate a large acceptance of the ion beam. At low energies and high currents, prior art implanters produce a beam at the substrate which tends to be large, with a large angular divergence (e.g., a half-angle of up to seven degrees). In contrast, medium current implanters typically incorporate a serial (one wafer at a time) process chamber, which offers a high tilt capability (e.g., up to 60 degrees from the substrate normal). The ion beam is typically electromagnetically or electrodynamicaily scanned across the wafer at a high frequency, up to about 2 kilohertz in one dimension (e.g., laterally) and mechanically scanned at a low frequency of less than 1 Hertz in an orthogonal direction (e.g., vertically), to obtain areal coverage and provide dose uniformity over the substrate. Process requirements for medium current implants are more complex than those for high current implants. In order to meet typical commercial implant dose uniformity and repeatability requirements of a variance of only a few per cent, the ion beam must possess excellent angular and spatial uniformity (angular uniformity of beam on wafer of ≦1deg, for example). Because of these requirements, medium current beam lines are engineered to give superior beam control at the expense of reduced acceptance. That is, the transmission efficiency of the ions through the implanter is limited by the emittance of the ion beam. Presently, the generation of higher current (about 1 mA) ion beams at low (<10 keV) energy is problematic in serial implanters, such that wafer throughput is unacceptably low for certain lower energy implants (for example, in the creation of source and drain structures in leading edge CMOS processes). Similar transport problems also exist for batch implanters (processing many wafers mounted on a spinning disk) at the low beam energies of <5 keV per ion.

While it is possible to design beam transport optics which are nearly aberration-free, the ion beam characteristics (spatial extent, spatial uniformity, angular divergence and angular uniformity) are nonetheless largely determined by the emittance properties of the ion source itself (i.e., the beam properties at ion extraction which determine the extent to which the implanter optics can focus and control the beam as emitted from the ion source). The use of cluster beams instead of monomer beams can significantly enhance the emittance of an ion beam by raising the beam transport energy and reducing the electrical current carried by the beam. However, prior art ion sources for ion implantation are not effective at producing or preserving ionized clusters of the required N- and P-type dopants. Thus, there is a need for cluster ion and cluster ion source technology in order to provide a better-focused, more collimated and more tightly controlled ion beam on target, and in addition to provide higher effective dose rates and higher throughputs in semiconductor manufacturing.

An alternative approach to beam line ion implantation for the doping of semiconductors is so-called “plasma immersion”. This technique is known by several other names in the semiconductor industry, such as PLAD (PLAsma Doping), PPLAD (Pulsed PLAsma Doping, and PI³ (Plasma Immersion ion Implantation). Doping using these techniques requires striking a plasma in a large vacuum vessel that has been evacuated and then backfilled with a gas containing the dopant of choice such as boron triflouride, diborane, arsine, or phosphine. The plasma by definition has positive ions, negative ions and electrons in it. The target is then biased negatively thus causing the positive ions in the plasma to be accelerated toward the target. The energy of the ions is described by the equation U=QV, where U is the kinetic energy of the ions, Q is the charge on the ion, and V is the bias on the wafer. With this technique there is no mass analysis. All positive ions in the plasma are accelerated and implanted into the wafer. Therefore extremely clean plasma must be generated. With this technique of doping a plasma of diborane, phosphine or arsine gas is formed, followed by the application of a negative bias on the wafer. The bias can be constant in time, time-varying, or pulsed. Dose can be parametrically controlled by knowing the relationship between pressure of the vapor in the vessel, the temperature, the magnitude of the biasing and the duty cycle of the bias voltage and the ion arrival rate on the target. It is also possible to directly measure the current on the target. While Plasma Doping is considered a new technology in development, it is attractive since it has the potential to reduce the per wafer cost of performing low energy, high dose implants, particularly for large format (e.g., 300 mm) wafers. In general, the wafer throughput of such a system is limited by wafer handling time, which includes evacuating the process chamber and purging and re-introducing the process gas each time a wafer or wafer batch is loader into the process chamber. This requirement has reduced the throughput of Plasma Doping systems to about 100 wafers per hour (WPH), well below the maximum mechanical handling capability of beamline ion implantation systems, which can process over 200 WPH.

### Negative Ion Implantation

It has recently been recognized (see, for example, Junzo Ishikawa et al., “Negative-Ion Implantation Technique”, Nuclear Instruments and Methods in Physics Research B 96 (1995) 7-12.) that implanting negative ions offers advantages over implanting positive ions. One very important advantage of negative ion implantation is to reduce the ion implantation-induced surface charging of VLSI devices in CMOS manufacturing. In general, the implantation of high currents (on the order of 1 mA or greater) of positive ions creates a positive potential on the gate oxides and other components of the semiconductor device which can easily exceed gate oxide damage thresholds. When a positive ion impacts the surface of a semiconductor device, it not only deposits a net positive charge, but liberates secondary electrons at the same time, multiplying the charging effect. Thus, equipment vendors of ion implantation systems have developed sophisticated charge control devices, so-called electron flood guns, to introduce low-energy electrons into the positively-charged ion beam and onto the surface of the device wafers during the implantation process. Such electron flood systems introduce additional variables into the manufacturing process, and cannot completely eliminate yield losses due to surface charging. As semiconductor devices become smaller and smaller, transistor operating voltages and gate oxide thicknesses become smaller as well, reducing the damage thresholds in semiconductor device manufacturing, further reducing yield. Hence, negative ion implantation potentially offers a substantial improvement in yield over conventional positive ion implantation for many leading-edge processes.

### SUMMARY OF THE INVENTION

An important object of the present invention is to provide for relatively high dose, low-energy implants of boron into a semiconductor substrate.

A further object of the present invention is to provide a method of manufacturing a semiconductor device, this method being capable of forming ultra-shallow impurity-doped regions of P-type (i.e., acceptor) conductivity in a semiconductor substrate, and furthermore to do so with high productivity.

Another object of this invention is to provide a method of manufacturing a semiconductor device, this method being capable of forming ultra-shallow impurity-doped regions of P-type (i.e., acceptor) conductivity in a semiconductor substrate by the implantation of ion beams formed from ionizing carborane molecules, e.g., C₂B₁₀H₁₂, C₂B₈H₁₀ and C₄B₁₈H₂₂, by direct electron impact and by arc discharge

According to one aspect of this invention, there is provided a method of implanting cluster ions comprising the steps of: providing a supply of molecules which each contain a plurality of dopant atoms into an ionization chamber, ionizing said molecules into dopant cluster ions, extracting and accelerating the dopant cluster ions with an electric field, selecting the desired cluster ions by mass analysis, modifying the final implant energy of the cluster ion through post-analysis ion optics, and implanting the dopant cluster ions into a semiconductor substrate.

An object of this invention is to provide a method that allows the semiconductor device manufacturer to ameliorate the difficulties in extracting low energy ion beams by implanting a cluster of n dopant atoms (n=18 in the case of C₄B₁₈Hₓ⁺) rather than implanting a single atom at a time. The cluster ion implant approach provides the equivalent of a much lower energy monatomic implant since each atom of the cluster is implanted with an energy of approximately E/n. Thus, the implanter is operated at an extraction voltage approximately n times higher than the required implant energy, which enables higher ion beam current, particularly at the low implantation energies required by USJ formation. In addition, each milliamp of cluster current provides the equivalent of 18 mA of monomer boron. Considering the ion extraction stage, the relative improvement in transport efficiency enabled by cluster ion implant can be quantified by evaluating the Child-Langmuir limit. It is recognized that this limit can be approximated by:

Jₘₐₓ=1.72 (Q/A)^{1/2}V^{3/2}d⁻². (1)

where Jₘₐₓ is in mA/cm², Q is the ion charge state, A is the ion mass in AMU, V is the extraction voltage in kV, and d is the gap width in cm. In practice, the extraction optics used by many ion implanters can be made to approach this limit. By extension of equation (1), the following figure of merit, Δ, can be defined to quantify the increase in throughput, or implanted dose rate, for a cluster ion implant relative to monatomic implantation:

Δ32 n (Uₙ/U₁)^{3/2} (mₙ/m₁)^{-1/2}, (2)

Here, Δ is the relative improvement in dose rate (atoms/sec) achieved by implanting a cluster with n atoms of the dopant of interest at an energy Uₙ relative to the single atom implant of an atom of mass m₁ at energy U₁, where Uᵢ=eV. In the case where Uₙ is adjusted to give the same dopant implantation depth as the monatomic (n=1) case, equation (2) reduces to:

Δ=n². (3)

Thus, the implantation of a cluster of n dopant atoms has the potential to provide a dose rate n² higher than the conventional implant of single atoms. In the case of B₁₈Hₓ, this maximum dose rate improvement is more than 300. The use of cluster ions for ion implant clearly addresses the transport of low energy (particularly sub-keV) ion beams. It is to be noted that the cluster ion implant process only requires one electrical charge per cluster, rather than having every dopant atom carrying one electrical charge, as in the conventional case. The transport efficiency (beam transmission) is thus improved, since the dispersive Coulomb forces are reduced with a reduction in charge density importantly, this feature enables reduced wafer charging, since for a given dose rate, the electrical beam current incident on the wafer is dramatically reduced. Also, since the present invention produces copious amounts of negative ions of boron hydrides, such as B₁₈Hₓ⁻, it enables the commercialization of negative ion implantation at high dose rates. Since negative ion implantation produces less wafer charging than positive ion implantation, and since these electrical currents are also much reduced through the use of clusters, yield loss due to wafer charging can be further reduced. Thus, implanting with clusters of n dopant atoms rather than with single atoms ameliorates basic transport problems in low energy ion implantation and enables a dramatically more productive process.

Enablement of this method requires the formation of the cluster ions. The prior art ion sources used in commercial ion implanters produce only a small fraction of primarily lower-order (e.g., n=2) clusters relative to their production of monomers, and hence these implanters cannot effectively realize the low energy cluster beam implantation advantages listed above. Indeed, the intense plasmas provided by many conventional ion sources rather dissociate molecules and clusters into their component elements. The novel ion source described herein produces cluster ions in abundance due to its use of a “soft” ionization process, namely electron-impact ionization. The ion source of the present invention is designed expressly for the purpose of producing and preserving dopant cluster ions. Instead of striking an arc discharge plasma to create ions, the ion source of the present invention uses electron-impact ionization of the process gas by electrons injected in the form of one or more focused electron beams.

### DESCRIPTION OF THE DRAWINGS

These and other advantages of the present invention will be readily understood with reference to the following specification and attached drawing wherein:

FIG. 1 is a schematic of an exemplary vapor delivery system and ion source for use with the present invention.

FIG. 1A is a schematic diagram of an exemplary high-current cluster ion implantation system in accordance with the present invention.

FIG. 2 represents a CMOS device structure showing relevant implants

FIG. 3 is an exemplary soft-ionization ion source in accordance with the present invention.

FIG. 4 is a schematic diagram of an exemplary dual-mode ion source having both a soft-ionization mode and an arc-discharge mode for use the the present invention.

FIG. 5 is a ball-and-stick model of the m-C₂B₁₀H₁₂ molecule.

FIG. 6 is a ball-and-stick model of the C₄B₁₈H₂₂ molecule.

FIG. 7 is a graphical illustration of the positive ion mass spectrum of o-C₂B₁₀H₁₂ generated with the ion source of the present invention, collected at low mass resolution.

FIG. 8 is a diagram of a CMOS fabrication sequence during formation of the NMOS drain extension.

FIG. 9 is a diagram of a CMOS fabrication sequence during formation of the PMOS drain extension.

FIG. 10 is a diagram of a semiconductor substrate in the process of manufacturing a NMOS semiconductor device, at the step of N-type drain extension implant.

FIG. 11 is a diagram of a semiconductor substrate in the process of manufacturing a NMOS semiconductor device, at the step of the source/drain implant.

FIG. 12 is a diagram of a semiconductor substrate in the process of manufacturing an PMOS semiconductor device, at the step of P-type drain extension implant.

FIG. 13 is a diagram of a semiconductor substrate in the process of manufacturing a PMOS semiconductor device, at the step of the source/drain implant.

### DETAILED DESCRIPTION

### Cluster Ion Implantation System

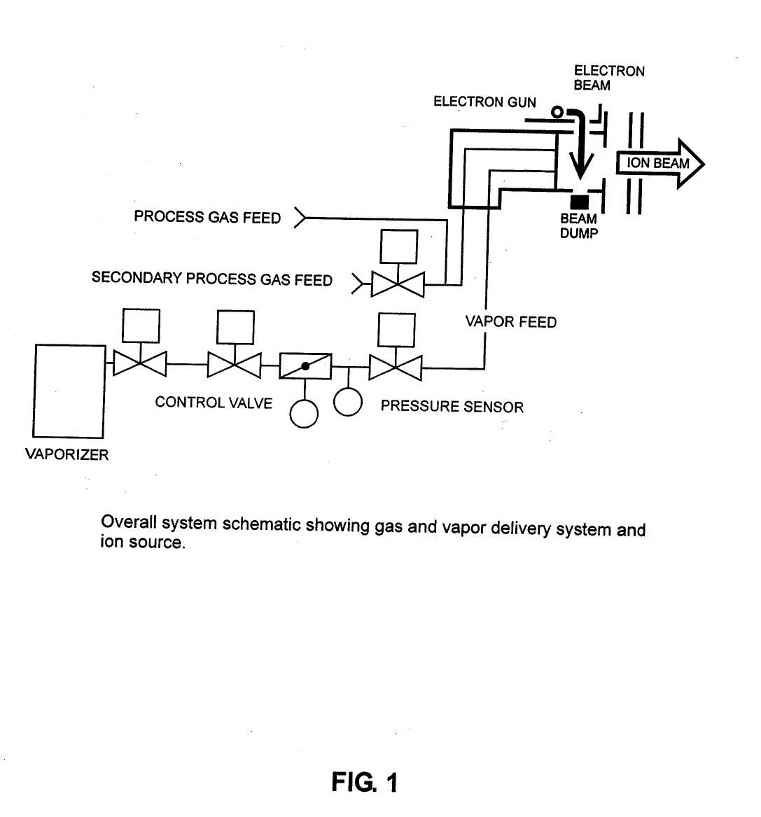

FIG. 1A is a schematic diagram of a cluster ion implantation system of the high current type for use with the present invention. In particular, the present invention relates to the use of source materials of carborane molecules such as, C₂B₁₀H₁₂, C₂B₈H₁₀ and C₄B₁₈H₂₂ that are ionized and used as a dopant material for a semiconductor substrate. Configurations for ion implantation devices other than that shown in FIG. 1A are possible. In general, the electrostatic optics of ion implanters employ slots (apertures displaying a large aspect ratio in one dimension) embedded in electrically conductive plates held at different potentials, which tend to produce ribbon beams, i.e., beams which are extended in one dimension. This approach has proven effective in reducing space-charge forces, and simplifies the ion optics by allowing the separation of focusing elements in the dispersive (short axis) and non-dispersive (long axis) directions. The cluster ion source 10 of the present invention is coupled with an extraction electrode 220 to create an ion beam 200 which contains cluster ions, such as C₄B₁₈Hₓ⁺, C₂B₁₀Hₓ⁺ and C₂B₈Hₓ⁺ ions, derived from carborane molecules, e.g., C₄B₁₈H₂₂, C₂B₁₀H₁₂ and C₂B₈H₁₀ source materials, respectively. These ions are extracted from an elongated slot in ion source 10, called the ion extraction aperture, by an extraction electrode 220, which also incorporates slot lenses of somewhat larger dimension than those of the ion extraction aperture; typical dimensions of the ion extraction aperture may be, for example, 50 mm tall by 8 mm wide, but other dimensions are possible. The electrode may be an accel-decel electrode in a tetrode configuration, i.e., the electrode extracts ions from the ion source at a higher energy and then decelerates them prior to their exiting the electrode.

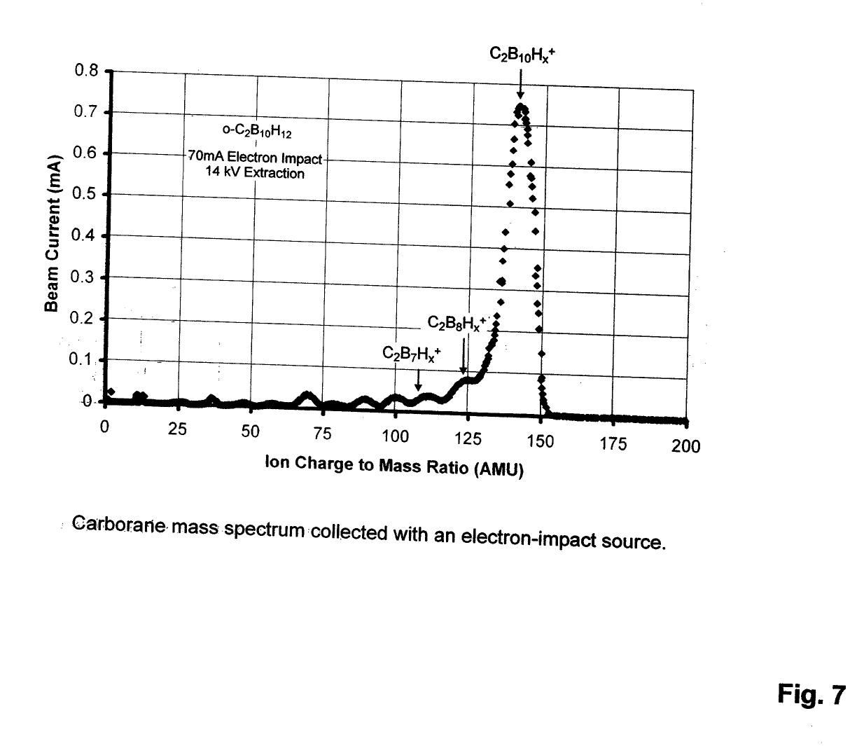

The ion beam 200 (FIG. 1A) typically contains ions of many different masses, i.e., all of the ion species of a given charge polarity created in the ion source 210, for example, as shown in FIG. 7. The ion beam 200 then enters an analyzer magnet 230. The analyzer magnet 230 creates a dipole magnetic field within the ion beam transport path as a function of the current in the magnet coils; the direction of the magnetic field is shown as normal to the plane of FIG. 1A, which is also along the non-dispersive axis of the one-dimensional optics. The analyzer magnet 230 is also a focusing element which forms a real image of the ion extraction aperture (i.e., the optical “object” or source of ions) at the location of the mass resolving aperture 270. Thus, mass resolving aperture 270 has the form of a slot of similar aspect ratio but somewhat larger dimension than the ion extraction aperture. In one embodiment, the width of resolving aperture 270 is continuously variable to allow selection of the mass resolution of the implanter. A primary function of the analyzer magnet 230 is to spatially separate, or disperse, the ion beam into a set of constituent beamlets by bending the ion beam in an arc whose radius depends on the mass-to-charge ratio of the discrete ions. Such an arc is shown in FIG. 1A as a beam component 240, the selected ion beam. The analyzer magnet 230 bends a given beam along a radius given by Equation (4) below:

R=(2mU)^{1/2}/qB, (4)

where R is the bending radius, B is the magnetic flux density, m is the ion mass, U is the ion kinetic energy and q is the ion charge state.

The selected ion beam is comprised of ions of a narrow range of mass-energy product only, such that the bending radius of the ion beam by the magnet sends that beam through mass resolving aperture 270. The components of the beam that are not selected do not pass through the mass-resolving aperture 270, but are intercepted elsewhere. For beams with smaller mass-to-charge ratios m/q 250 than the selected beam 240, for example comprised of hydrogen ions having a mass of 1 or 2 AMU, the magnetic field induces a smaller bending radius and the beam intercepts the inner radius wall 300 of the magnet vacuum chamber, or elsewhere upstream of the mass resolving aperture. For beams with larger mass-to-charge ratios 260 than the selected beam 240, the magnetic field induces a larger bending radius, and the beam strikes the outer radius wall 290 of the magnet chamber, or elsewhere upstream of the mass resolving aperture. As is well established in the art, the combination of analyzer magnet 230 and mass resolving aperture 270 form a mass analysis system which selects the ion beam 240 from the multi-species beam 200 extracted from the ion source 10. The selected beam 240 then passes through a post-analysis acceleration/deceleration electrode 310. This stage 310 can adjust the beam energy to the desired final energy value required for the specific implantation process. For example, in low-energy, high-dose process higher currents can be obtained if the ion beam is formed and transported at a higher energy and then decelerated to the desired, lower implant ion energy prior to reaching the wafer. The post-analysis acceleration/deceleration lens 310 is an electrostatic lens similar in construction to decel electrode 220. To produce low-energy positive ion beams, the front portion of the implanter is enclosed by terminal enclosure 208 and floated below earth ground. A grounded Faraday cage 205 surrounds the enclosure 208 for safety reasons. Thus, the ion beam can be transported and mass-analyzed at higher energies, and decelerated prior to reaching the workpiece. Since decel electrode 300 is a strong-focusing optic, dual quadrupoles 320 refocus ion beam 240 to reduce angular divergence and spatial extent. In order to prevent ions which have undergone charge-exchange or neutralization reactions between the resolving aperture and the substrate 312 (and therefore do not possess the correct energy) from propagating to substrate 312, a neutral beam filter 310a (or “energy filter”) is incorporated within this beam path. For example, the neutral beam filter 310a shown incorporates a “dogleg” or small-angle deflection in the beam path which the selected ion beam 240 is constrained to follow through an applied DC electromagnetic field; beam components which have become electrically neutral or multiply-charged, however, would necessarily not follow this path. Thus, only the ion of interest and with the correct ion energy is passed downstream of the exit aperture 314 of the filter 310a.

Once the beam is shaped by a quadrupole pair 320 and filtered by a neutral beam filter 310a , the ion beam 240 enters the wafer process chamber 330, also held in a high vacuum environment, where it strikes the substrate 312 which is mounted on a spinning disk 315. Various materials for the substrate are suitable with the present invention, such as silicon, silicon-on-insulator strained superlaftice substrate and a silicon germanium (SiGe) strained superlaftice substrate. Many substrates may be mounted on the disk so that many substrates may be implanted simultaneously, i.e., in batch mode. In a batch system, spinning of the disk provides mechanical scanning in the radial direction, and either vertical or horizontal scanning of the spinning disk is also effected at the same time, the ion beam remaining stationary.

The use of carborane cluster ion beams, such as C₄B₁₈Hₓ⁺, C₂B₈H₁₀ and C₂B₁₀Hₓ⁺ allows the beam extraction and transmission to take place at higher energies than would be the case for the monomer, B⁺ . . . . Upon striking the target, the ion energy is partitioned by mass ratio of the individual, constituent atoms. For an C₄B₁₈Hₓ⁺ ion beam, the effective boron energy is about 10.8/260 of the beam energy, because an average boron atom has a mass of 10.8 amu and the molecule has an average mass of about 260 amu. This allows the beam to be extracted and transported at 24 times the implant energy. Additionally the dose rate is 18 times higher than for a monomer ion. This results in higher throughput and less charging of the wafer. Wafer charging is reduced because there is only one charge for 18 atoms implanted into the wafer instead of one charge for every atom implanted with a monomer beam. Similarly, since the peak mass (see FIG. 7) of the C₂B₁₀Hₓ⁺ ion is at about 143 amu, the ratio of beam energy to boron implant energy is about 13, and the increase in boron dose rate is a factor of 10 since there are 10 boron atoms per ion delivered to the wafer.

### Plasma Doping With Clusters

An alternative approach to beam line ion implantation for the doping of semiconductors is so-called “plasma immersion”. This technique is known by several other names in the semiconductor industry, such as PLAD (PLAsma Doping), PPLAD (Pulsed PLAsma Doping, and PI³ (Plasma Immersion Ion Implantation). Doping using these techniques requires striking a plasma in a large vacuum vessel that has been evacuated and then backfilled with a gas containing the dopant of choice such as carborane molecules, e.g., C₂B₁₀H₁₂, C₂B₈H₁₀ and C₄B₁₈H₂₂ vapor. The plasma by definition has positive ions, negative ions and electrons in it. The target is then biased negatively thus causing the positive ions in the plasma to be accelerated toward the target. The energy of the ions is described by the equation U=QV, where U is the kinetic energy of the ions, Q is the charge on the ion, and V is the bias on the wafer. With this technique there is no mass analysis. All positive ions in the plasma are accelerated and implanted into the wafer. Therefore extremely clean plasma must be generated. With this technique of doping, a vapor of carborane cluster molecules, such as C₄B₁₈H₂₂, C₂B₈H₁₀ or C₂B₁₀H₁₂, can be introduced into the vessel and a plasma ignited, followed by the application of a negative bias on the wafer. The bias can be constant in time, time-varying, or pulsed. The use of these clusters will be beneficial since the ratio of dopant atoms to hydrogen (e.g., using C₄B₁₈H₂₂ versus B₂H₆ and AS₄Hₓ versus AsH₃) is greater for hydride clusters than for simple hydrides, and also the dose rates can be much higher when using clusters. Dose can be parametrically controlled by knowing the relationship between pressure of the vapor in the vessel, the temperature, the magnitude of the biasing and the duty cycle of the bias voltage and the ion arrival rate on the target. It is also possible to directly measure the current on the target. As with beam line implantation, using o-carborane would yield a 10 times enhancement in dose rate and 13 times higher accelerating voltages required if o-carborane were the vapor of choice. If AS₄Hₓ were used there would be a four times dose rate enhancement and about a four times the voltage required. There would also be reduced changing as with the beam line implants utilizing clusters.

### Soft-Ionization Source System and Ion Implantation System

An Implanter source must have a carefully regulated supply of feed gas in order to provide a stable ion beam. Conventional ion sources use mass flow controllers (MFC's) for this function. However, MFC's are not able to regulate vapor flow rates for low-temperature solids such as octadecaborane, decaborane and heptaphosphane due to their requirement for a relatively high inlet pressure and pressure drop across the MFC. FIG. 1 shows an example of a valve network that provides regulated molecular flow of gas vapor to an ion source.

As described in more detail in International Publication No. WO 2005/060602, published on Jul. 7, 2005, hereby incorporated by reference, the system depicted in FIG. 1 consists of a vaporizer device capable of sublimating solids at a sufficient rate to provide a positive pressure across a conductance throttling device, and a vaporizer isolation valve to provide positive shut off of vapors from the vaporizer. A variable conductance is achieved using a commercial available servo-actuated vacuum butterfly valve controlled with a PID controller. Feedback control to the servo controller comes from a downstream heated pressure transducer. Other valves are shown that aid in vacuum pump down and venting for service.

### Ion Source Detail

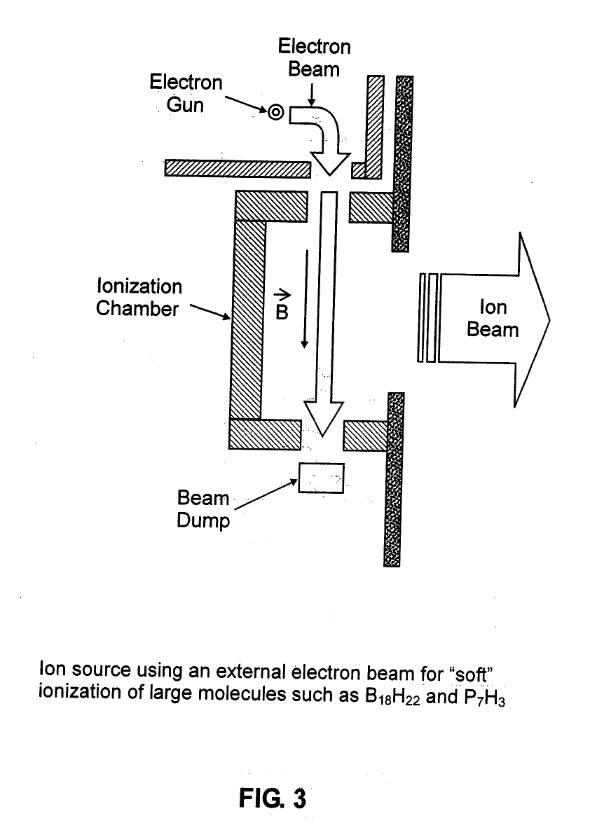

An exemplary direct electron impact ion source is shown in FIG. 1, and in greater detail in FIG. 3. This exemplary ion source is described in detail in U.S. Pat. No. 7,023,138, hereby incorporated by reference, uses electron impact to provide the gentle ionization necessary to preserve the integrity of the molecules being ionized. The design of the source takes advantage of the remote electron emitter location made possible by the electron injection optics. By placing the emitter as shown in FIGS. 1 and 3, filament wear associated with ion erosion is minimized, helping to ensure long filament life. Alternative ion sources are also suitable for use with the present invention, such as disclosed in U.S. Pat. No. 7,022,999, hereby incorporated by reference.

The ion source of FIG. 3 is a soft ionization ion source which incorporates an external electron gun to generate an intense electron beam which is injected into the source ionization chamber. An externally generated electron beam creates a stream of ions just behind the long rectangular slot from which ions are extracted by the implanter optics.

The electron gun creates an energetic electron beam of, for example, between 1 mA and 100 mA, which, in the case of the exemplary ion source illustrated in FIG. 1, is then deflected through 90 degrees by a magnetic dipole field. Since the electron gun is remote from the ionization chamber and has no line-of sight to the process gas, it resides in the high vacuum environment of the implanter's source housing, resulting in a long emitter lifetime. The deflected electron beam enters the source ionization chamber though a small entrance aperture. Once within the ionization chamber, the electron beam is guided along a path parallel to and directly behind the ion extraction slot by a uniform axial magnetic field of about, for example, 100 Gauss produced by a permanent magnetic yoke surrounding the ionization chamber. Ions are thus created along the electron beam path and adjacent to the extraction slot. This serves to provide good extraction efficiency of the ions, such that an ion current density of up to, for example, 1 mA/cm² can be extracted from the source. The beam current dynamic range thus achieved is comparable to other sources; by varying emission current and also the flow of feed material into the source, a stable on-wafer electrical beam current of, for example, between 5 pA and 2 mA is achieved.

The ion source system is designed with the requirements of low temperature vaporization in mind. The vapor delivery system is designed to provide the thermal management necessary to avoid condensation and deposition by methods which include the creation of a positive temperature gradient along the vapor delivery path. In addition to controlling the wefted surface temperatures in the delivery system, it is desirable to control the temperature of the source and the extraction electrode to minimize the condensation and deposition of vapor residues. Experience suggests that while it is important to keep surfaces which come into contact with the material warm enough to avoid material deposition by cooling from the vapor phase, it is also necessary to avoid high temperatures. Thus the ion source system depicted in FIG. 1 and FIG. 3 is temperature-controlled to a narrow temperature range, for example as discussed in detail in International Publication No. WO 2005/060602 A2, hereby incorporated by reference.

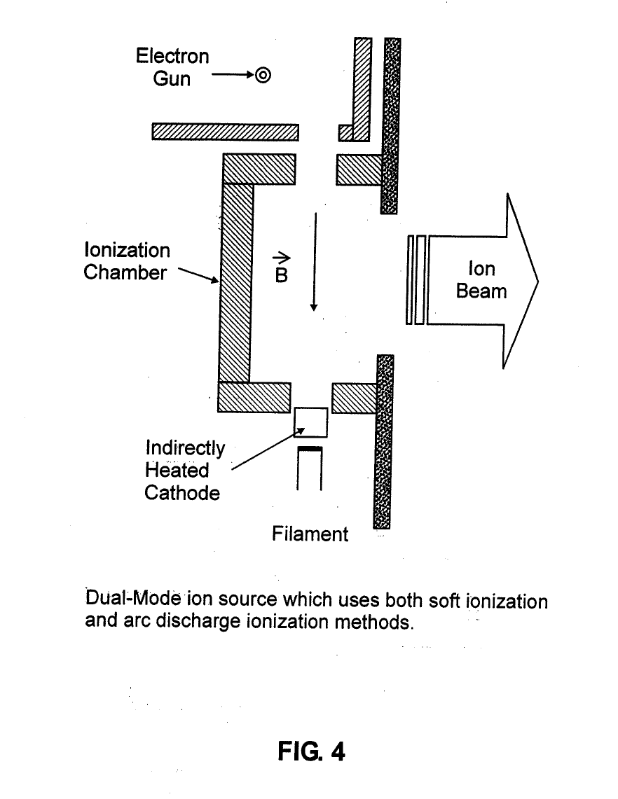

in accordance with an important aspect of the invention, the carborane cluster molecules , e.g., C₂B₁₀H₁₂, C₂B₈H₁₀ and C₄B₁₈H₂₂, may be ionized by either direct electron impact, as discussed above or by arc discharge. Various arc discharge ion sources are suitable. Foe example, FIG. 4 shows a dual-mode ion source that is described in detail in US Patent Application Publication No. US 2006/0097645 A1, hereby incorporated by reference. This source has both an external electron gun for use in a direct electron impact mode of operation and an indirectly-heated cathode which can produce a high density plasma by an arc discharge in an arc discharge mode of operation. ; The arc discharge method is known in the art as a means to produce high monomer and multiply-charged ion currents of several tens of milliamperes. Depending upon whether molecular ions or monomer ions are desired, this source can be operated in either a direct electron-impact mode or arc-discharge mode. As such, the dual mode source described above can be used to ionize the carborane molecules, i.e C₂B₁₀H₁₂, C₂B₈H₁₀ and C₄B₁₈H₂₂. Other arc discharge ion sources are also suitable.

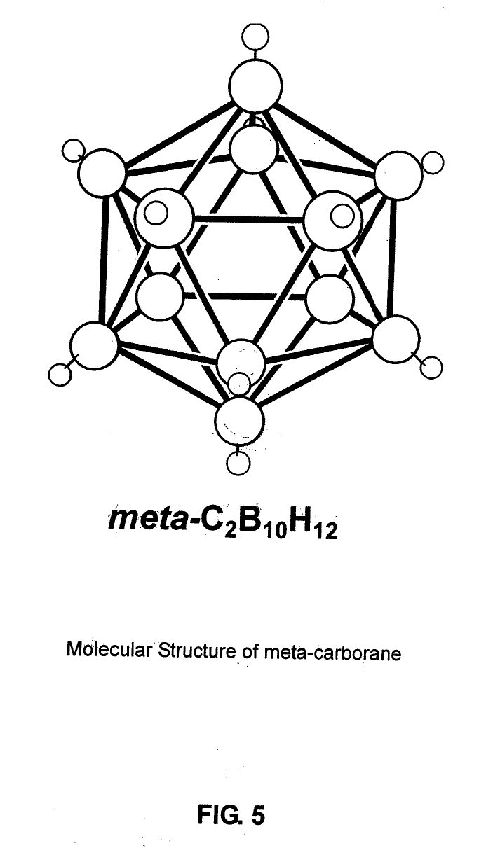

FIG. 5 illustrates the molecular structure of meta-C₂B₁₀H₁₂, and shows the relative positions of B atoms, C atoms and hydrogen atoms. Carborane materials of the form C₂B₁₀H₁₂ displays three distinct isomers: ortho, meta, and para, which differ according to the placement of the carbon atoms within the molecular “cage” structure. The principles of the present invention are applicable to all of the various isomers of C₂B₁₀H₁₂. C₂B₁₀H₁₂ is commercially available, for example, at Alpha Aesar in Massachusets.

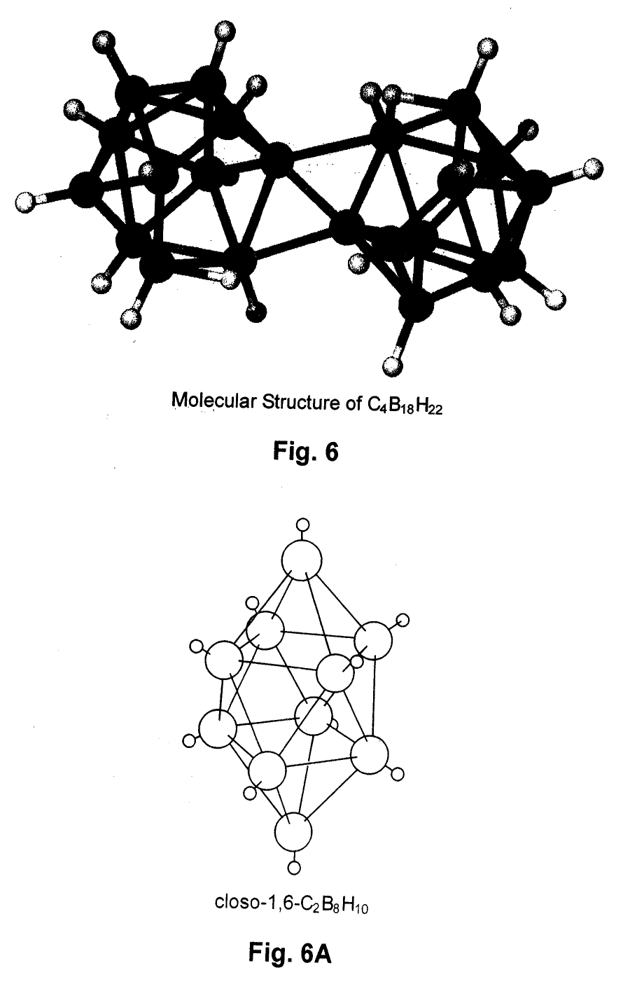

FIG. 6 illustrates the molecular structure of C₄B₁₈H₂₂ and shows the relative positions of B atoms, C atoms and hydrogen atoms. The synthesis path, i.e. recipe, for C₄B₁₈H₂₂ is known in the art. An exemplary synthesis path is disclosed in the literature in Inorg.Chem 2, 1089 (1963) and the Journal of the American Chemical Society, 79, 1006 (1957), as well as Plesek, J.; Hermanek, S. Chem. Ind. 1972, page 890. Subrtova V.; Linek, A.; Hasek, J. Acta. Crys. B, 1982, 3147-3149 (iso-C4B18H22 structure) Janousek, Z.; Stibr, B.; Fontaine, X. L. R.; Kennedy, J. D.; Thornton-Peft, M. JCS Dalton Trans. 1996, 3813-3818 (neo-C4B18H22 structure), all hereby incorporated by reference.

FIG. 6A illustrates the molecular structure of C₂B₈H₁₀. C₂B₈H₁₀ is discussed in Chemistry of the Elements, by N. N. Greenwood and A. Earnshaw, published by Bufterworth Heinemann, pages 206-208, hereby incorporated by reference.

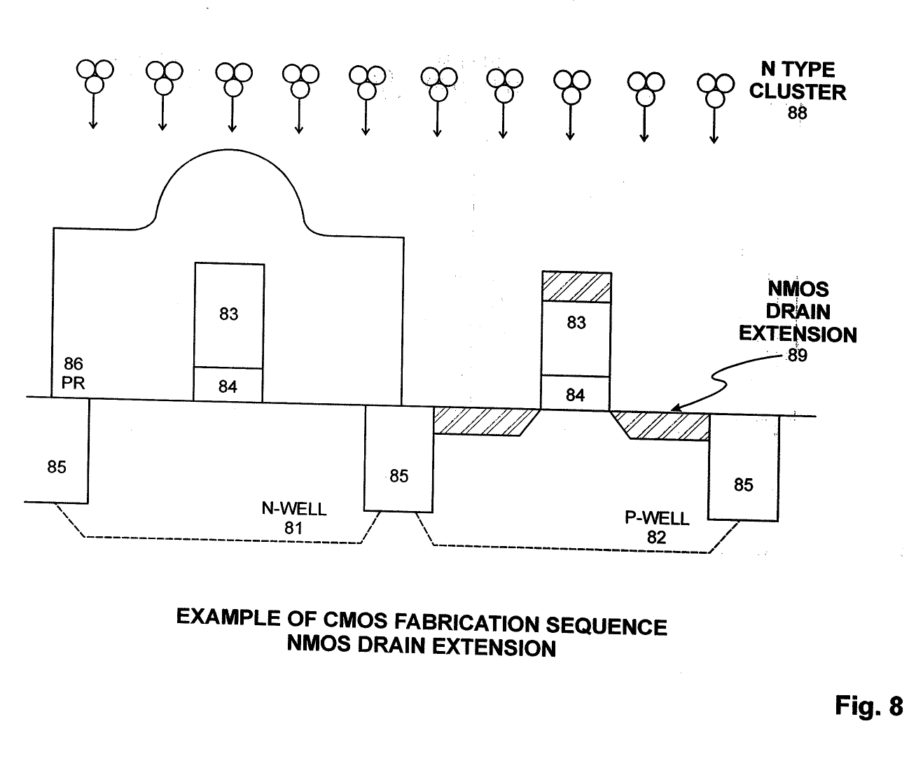

FIG. 7 shows a mass spectrum of o-carborane (C₂B₁₀H₁₂) collected under the following conditions: 1) The universal source depicted in FIG. 4 was operated in electron-impact mode, using an electron beam for ionization. The carborane material was incorporated into the vapor delivery system depicted in FIG. 1, and vaporized at a temperature of about 40C. The pressure at the throttle valve location as recorded by the pressure sensor of FIG. 1 was about 40 mTorr. The source and associated hardware was kept above the vaporizer temperature, at about 100C, to prevent condensation of the vapors. The source and vapor control system had been integrated into an Eaton GSD high-current implanter for purposes of testing. The spectrum displayed in FIG. 7 shows good preservation of the parent molecule peak, C₂B₁₀Hₓ⁺, at about 143 amu. The extraction voltage was 14 kV, so that the implantation energy per boron atom was about 1 keV. The effective boron dose rate represented in FIG. 8 is equivalent to about 7.5 mA of B⁺. The mass spectrum for C₄B₁₈H₂₂ and C₂B₈H₁₀is similar with good preservation of its parent molecule. In addition, C₂B₈Hₓ⁺ is one of the fragments illustrated in FIG. 7.

### Process Implications of Carborane Implantation

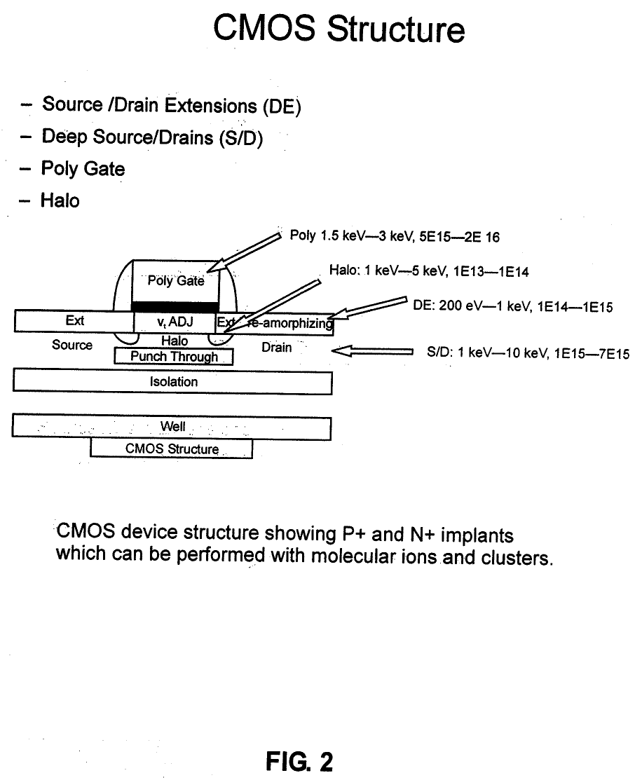

In principle, carboranes may be used for high-dose low-energy implants, as illustrated in FIG. 2. The presence of carbon introduces an additional variable versus pure boron or a pure borohydride, however early testing in our laboratories have yielded favorable results; similar as compared to a boron implant.

### Basic CMOS Transistor Structure

FIG. 2 shows the structure of a CMOS transistor. Indicated in FIG. 2 are implants which are appropriate for cluster implantation, both N- and P-type: Source/Drain (S/D), Drain Extension (DE), Halo (sometimes called Pocket Implant), and Poly Gate. These implants are considered highly doped, low-energy implants, and so are good candidates for the dose rate enhancement and low energy performance enabled by clusters.

In a transistor, there are three voltage terminals: The source, gate, and drain. Electrical current (negative for electrons, positive for holes) flows from source to drain. The region below the gate is called the channel, and the region below the active portion of the transistor the well; current therefore flows through the channel. This flow of current can be either on or off depending on the voltage applied to the gate. Thus, this is a two-state device. Depending on the sign of the carriers, the transistors are either NMOS (abundance of donor dopants in the well), or PMOS (abundance of acceptor dopants in the well). CMOS (Complementary MOS) uses an equal number of each type to simplify and increase the efficiency of the circuits in which the transistors are incorporated. Such a CMOS architecture is shown in FIG. 2. Boron is typically used for PMOS sources and drains; arsenic or phosphorus for NMOS sources and drains. The source and drain implants determine the effective field which drives current in the channel. They are conductive implants; that is, they are highly doped so that the average electrical conductivity is high. In short-channel devices, such as leading-edge logic and memory devices with gate lengths below 90 nm, this field is terminated by the drain extension implants, a very shallow, highly doped region which penetrates under the gate. This requires very low energy boron, arsenic and phosphorus implants. It is the drain extensions which determine the effective gate length of the transistors. It is important that the drain extension concentration profiles be as abrupt as possible in order to reduce device off-state leakage currents.

### Formation Of N- And P-Type Shallow Junctions

An important application of this method is the use of cluster carborane ion implantation for the formation of N- and P-type shallow junctions as part of a CMOS fabrication sequence. Such carborane carbon ion implants can be used in place of Boron for various applications including :source and drain extensions, polygate implants, halo implants and deep source implants. CMOS is the dominant digital integrated circuit technology in current use and its name denotes the formation of both N-channel and P-channel MOS transistors (Complementary MOS: both N and P) on the same chip. The success of CMOS is that circuit designers can make use of the complementary nature of the opposite transistors to create a better circuit, specifically one that draws less active power than alternative technologies. It is noted that the N and P terminology is based on Negative and Positive (N-type semiconductor has negative majority carriers, and vice versa), and the N-channel and P-channel transistors are duplicates of each other with the type (polarity) of each region reversed. The fabrication of both types of transistors on the same substrate requires sequentially implanting an N-type impurity and then a P-type impurity, while protecting the other type of devices with a shielding layer of photoresist. It is noted that each transistor type requires regions of both polarities to operate correctly, but the implants which form the shallow junctions are of the same type as the transistor: N-type shallow implants into N-channel transistors and P-type shallow implants into P-channel transistors.

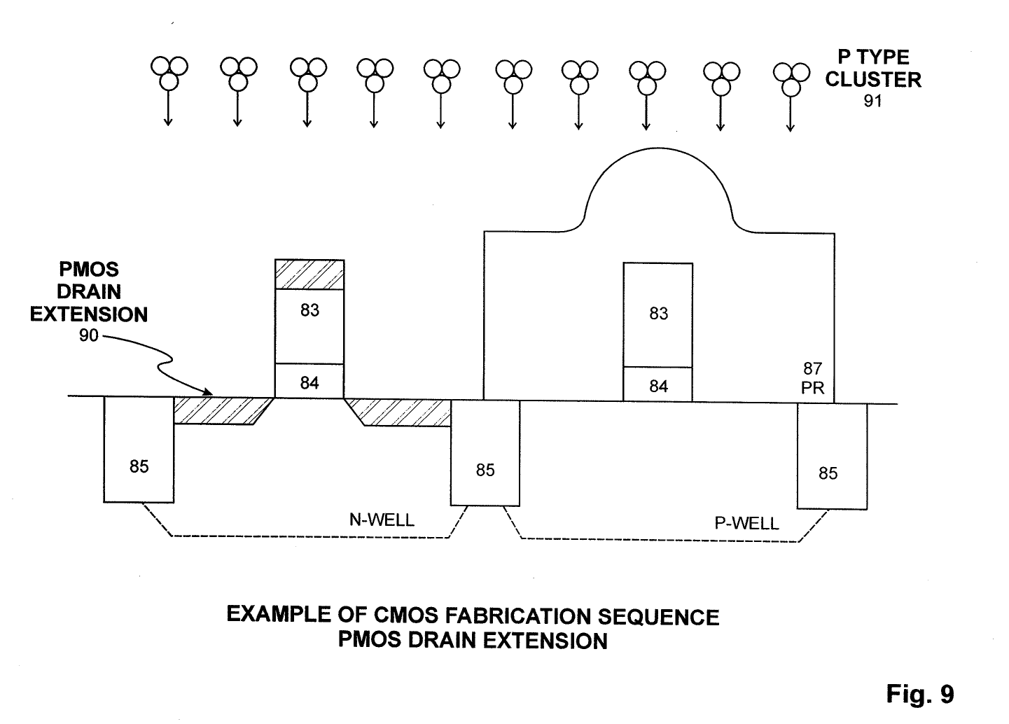

An example of this process is shown in FIGS. 8 and 9. In particular, FIG. 8 illustrates a method for forming the N-channel drain extension 89 through an N-type cluster implant 88, while FIG. 9 shows the formation of the P-channel drain extension 90 by a P-type cluster implant 91. It is to be noted that both N- and P-types of transistors requires shallow junctions of similar geometries, and thus having both N-type and P-type cluster implants is advantageous for the formation of advanced CMOS structures.

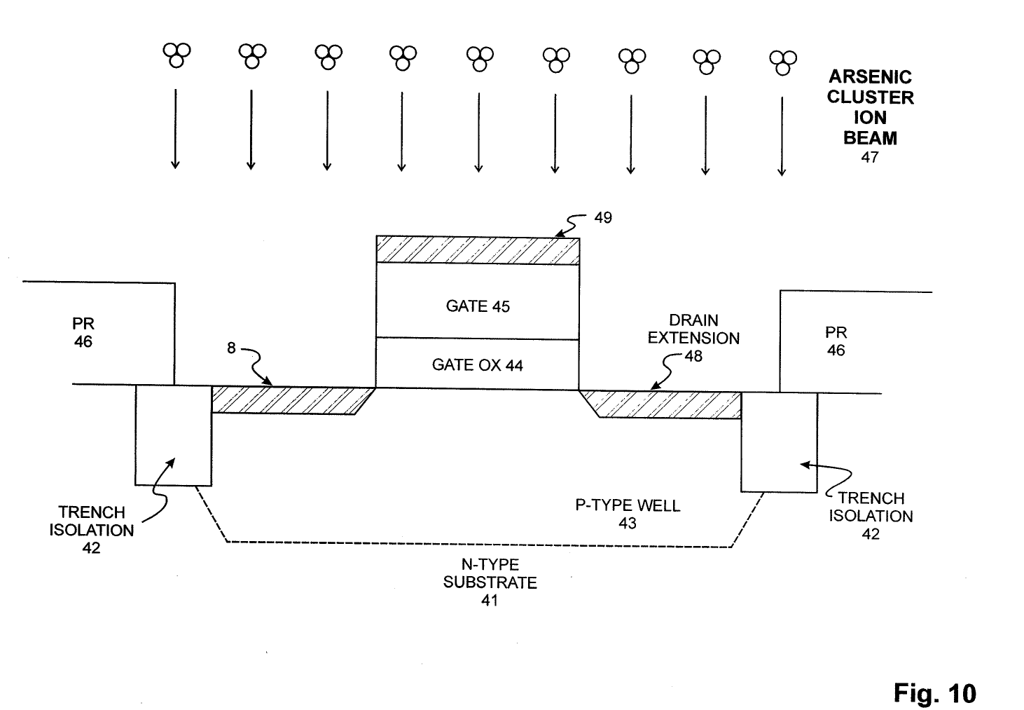

An example of the application of this method is shown in FIG. 10 for the case of forming an NMOS transistor. This figure shows semiconductor substrate 41 which has undergone some of the front-end process steps of manufacturing a semiconductor device. For example, the structure consists of a N-type semiconductor substrate 41 that has been processed through the P-well 43, trench isolation 42, and gate stack formation 44, 45 steps. An exemplary process for forming the gate stack, P-well and trench isolation is disclosed in International Patent Application No. PCT/US03/019085, filed on Jun. 18, 2003, entitled “A Semiconductor Device and Method of Fabricating a Semiconductor Device”, published as International Patent Publication No. WO 04/03970, hereby incorporated by reference.

The P-well 43 forms a junction with the N-type substrate 41 that provides junction isolation for the transistors in the well 43. The trench isolation 42 provides lateral dielectric isolation between the N- and P-wells (i.e., in the overall CMOS structure). The gate stack is constructed, with a gate oxide layer 44 and a polysilicon gate electrode 45, patterned to form a transistor gate stack. A photoresist 46 is applied and patterned such that the area for NMOS transistors is exposed, but other areas of the substrate 41 are shielded. After the photoresist 46 is applied, the substrate 41 is ready for the drain extension implant, which is the shallowest doping layer required by the device fabrication process. A typical process requirement for leading-edge devices of the 0.13 μm technology node is an arsenic implant energy of between 1 keV and 2 keV, and an arsenic dose of 5×10¹⁴ cm⁻². The cluster ion beam 47, As₄Hₓ⁺ in this case, is directed at the semiconductor substrate, typically such that the direction of propagation of the ion beam is normal to the substrate, to avoid shadowing by the gate stack. The energy of the As₄Hₓ⁺ cluster should be four times the desired As⁺ implant energy, e.g., between 4 keV and 8 keV. The clusters dissociate upon impact with the substrate, and the dopant atoms come to rest in a shallow layer near the surface of the semiconductor substrate, which forms the drain extension region 48. We note that the same implant enters the surface layer of the gate electrode 49, providing additional doping for the gate electrode. The process described in FIG. 10 is thus one important application of the proposed invention.

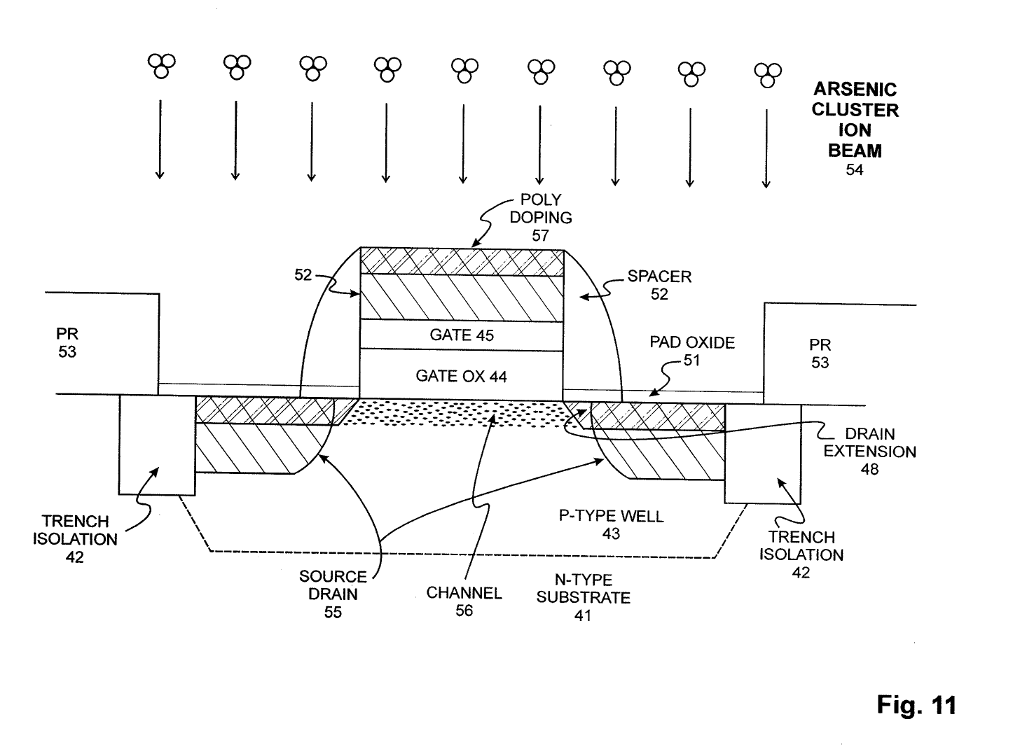

A further example of the application of this method is shown in FIG. 11: the formation of the deep source/drain regions. This figure shows the semiconductor substrate 41 of FIG. 10 after execution of further processes steps in the fabrication of a semiconductor device. The additional process steps include the formation of a pad oxide 51 and the formation of spacers 52 on the sidewalls of the gate stack. The pad oxide 51 is a thin layer of oxide (silicon dioxide) used to protect the exposed substrate areas, the top of the gate electrode 49 and the potentially exposed gate dielectric edge. The pad oxide 51 is typically thermally grown to a thickness of 5-10 nm. The spacer 52, on the other hand, is a region of dielectric, either silicon dioxide, silicon nitride, or a combination of these, which resides on the side of the gate stack and serves to insulate the gate electrode. It also serves as an alignment guide for the source/drain implant (e.g., 54), which must be spaced back from the gate edge for the transistor to operate properly. The spacers 52 are formed by the deposition of silicon dioxide and/or silicon nitride layers which are then plasma etched in a way to leave a residual layer on the side of the gate stack while clearing the dielectrics from the source/drain region.

At this point, after etching the spacers 52, a photoresist layer 53 is applied and patterned to expose the transistor to be implanted, an NMOS transistor in this example. Next, the ion implant to form the source and drain regions 55 is performed. Since this implant requires a high dose at low energy, it is an appropriate application of the proposed cluster implantation method. Typical implant parameters for the 0.13 nm technology node are approximately 6 keV per arsenic atom (54) at an arsenic dose of 5×10¹⁵ cm⁻², so it requires a 24 keV, 1.25×10¹⁵ cm⁻² As₄Hₓ⁺implant, a 12 keV, 2.5∴10¹⁵ cm⁻²As₂Hₓ⁺ implant, or a 6 keV, 5×10¹⁵ cm⁻² As⁺ implant. As shown in FIG. 10, the source and drain regions 55 are formed by this implant. These regions provide a high conductivity connection between the circuit interconnects (to be formed later in the process) and the intrinsic transistor defined by the drain extension 48 in conjunction with the channel region 56 and the gate stack 44, 45. Tlt may be noted that the gate electrode 45 can be exposed to this implant (as shown), and if so, the source/drain implant provides the primary doping source for the gate electrode. This is shown in FIG. 11 as the poly doping layer 57.

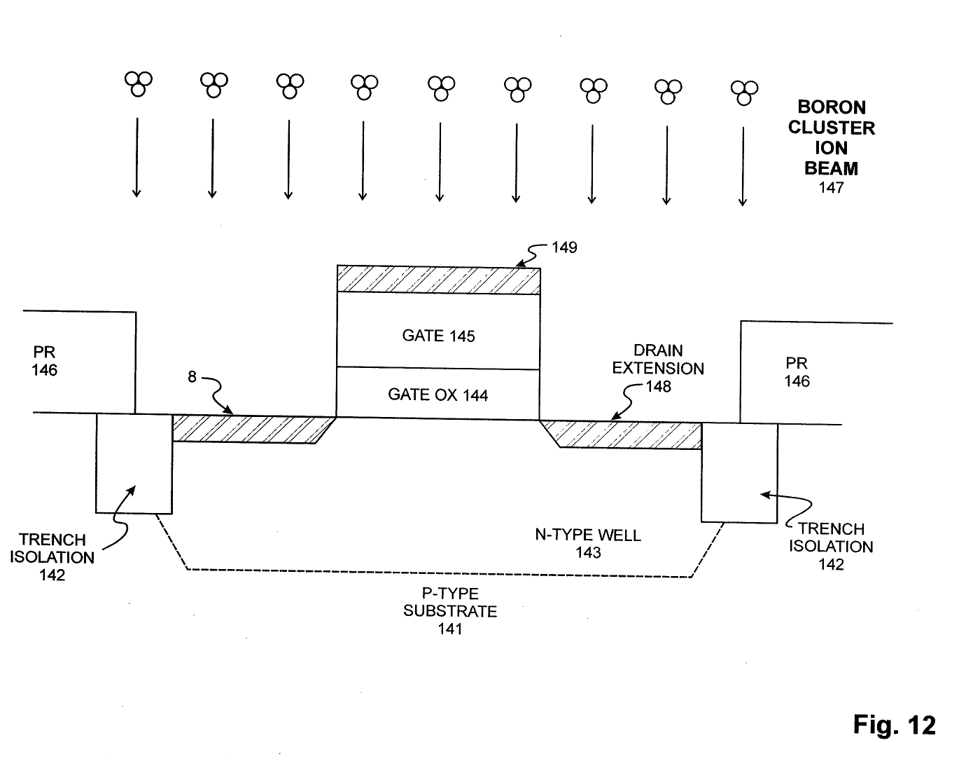

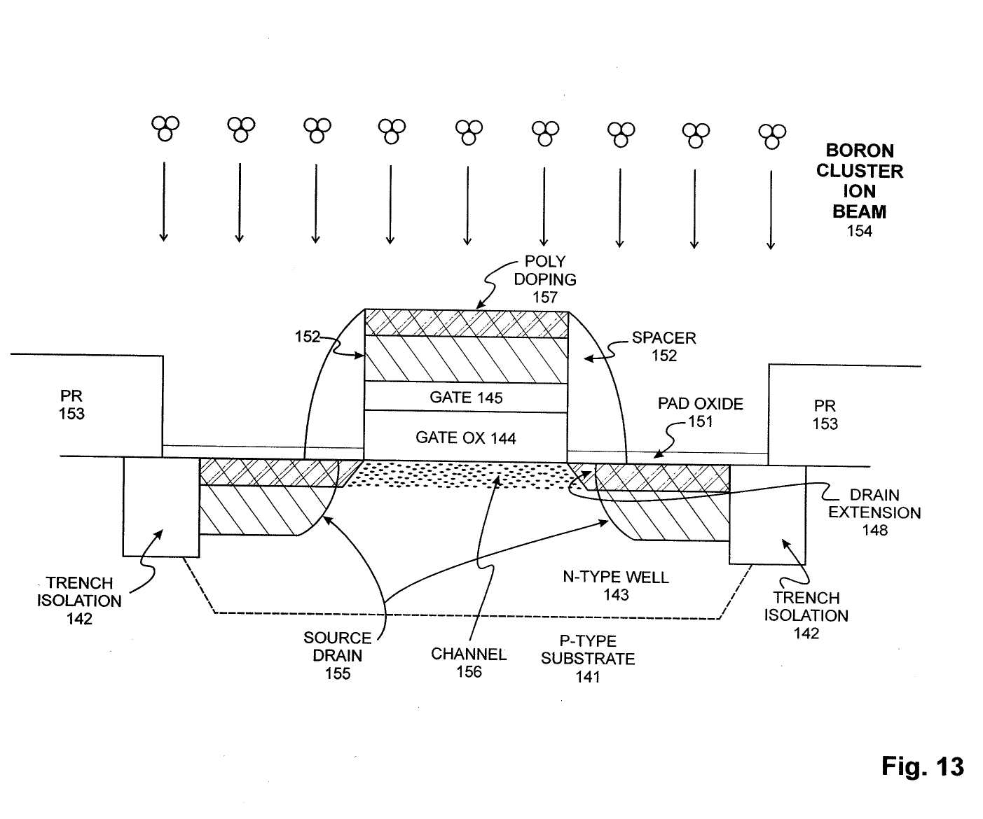

The detailed diagrams showing the formation of the PMOS drain extension 148 and PMOS source and drain regions 155 are shown in FIGS. 12 and 13, respectively. The structures and processes are the same as in FIGS. 11 and 12 with the dopant types reversed. In FIG. 12, the PMOS drain extension 148 is formed by the implantation of a boron cluster implant 147. Typical parameters for this implant would be an implant energy of 500 eV per boron atom with a dose of 5×10¹⁴ cm⁻², for the 0.13 um technology node. Thus, a B₁₈Hₓ⁺ implant at 211 AMU would be at 9.6 keV at an octadecaborane dose of 2.8×10¹³ cm⁻². FIG. 17 shows the formation of the PMOS source and drain regions 148, again by the implantation of a P-type cluster ion beam 154 such as octadecaborane. Typical parameters for this implant would be an energy of around 2 keV per boron atom with a boron dose of 5×10¹⁵ cm⁻² (i.e., 38.4 keV octadecaborane at 2.8×10¹⁴ cm⁻²) for the 0.13 um technology node.

In general, ion implantation alone is not sufficient for the formation of an effective semiconductor junction: a heat treatment is necessary to electrically activate the implanted dopants. After implantation, the semiconductor substrate's crystal structure is heavily damaged (substrate atoms are moved out of crystal lattice positions), and the implanted dopants are only weakly bound to the substrate atoms, so that the implanted layer has poor electrical properties. A heat treatment, or anneal, at high temperature (greater than 900C) is typically performed to repair the semiconductor crystal structure, and to position the dopant atoms substitutionally, i.e., in the position of one of the substrate atoms in the crystal structure. This substitution allows the dopant to bond with the substrate atoms and become electrically active; that is, to change the conductivity of the semiconductor layer. This heat treatment works against the formation of shallow junctions, however, because diffusion of the implanted dopant occurs during the heat treatment. Boron diffusion during heat treatment, in fact, is the limiting factor in achieving USJ's in the sub-0.1 micron regime. Advanced processes have been developed for this heat treatment to minimize the diffusion of the shallow implanted dopants, such as the “spike anneal”. The spike anneal is a rapid thermal process wherein the residence time at the highest temperature approaches zero: the temperature ramps up and down as fast as possible. In this way, the high temperatures necessary to activate the implanted dopant are reached while the diffusion of the implanted dopants is minimized. It is anticipated that such advanced heat treatments would be utilized in conjunction with the present invention to maximize its benefits in the fabrication of the completed semiconductor device.

### Amorphization for Channeling Control

To maintain abruptness and limit off-state leakage, Si or Ge pre-amorphization implants are usually conducted to eliminate channeling, which tends to create long tails in the as-implanted profiles. Unfortunately, end-of-range defects created by the implantation of Si or Ge can result in increased leakage elsewhere in the device. It is a significant benefit of cluster and molecular ion implantation that these pre-amorphization implants are not required, since the large molecular ions, such as C₄B₁₈Hₓ⁺ and C₂B₁₀Hₓ⁺ are known to amorphize the silicon. Thus, the risk of leakage caused by end-or-range defects is avoided when molecular ions are used. As also indicated in FIG. 2, the table below outlines typical P+ and N+ implants which benefit from the use of cluster and molecular ion implants:

TABLE I
USJ implants which are good candidates for cluster and molecular ion
implants

| | | | Energy | |
|---|---|---|---|---|
| Implant | Species | Dose Range | Range | |
| Drain | B, P, As | 1E14-1E15 | 0.20-1 | keV |
| Extension | | | | |
| Source/Drain | B, As | 1E15-7E15 | 1-10 | keV |
| Halo | B, P | 1E13-1E14 | 1-5 | keV |
| Poly Gate | B, P | 8E15-3E16 | 1-5 | keV |

### Halo Implants

Halo implants are important for ameliorating so-called “short channel” effects, that is, they adjust the field within the channel to preserve a well-defined threshold voltage characteristic. In NMOS devices the Halo is P-type (e.g., boron), and in PMOS devices the Halo is N-type (e.g., phosphorus). The Halo is a high-angle implant is introduced after any Si or Ge pre-amorphization implant if one is used and in the same lithography step used to dope the source/drain extension regions. Since the Halo implant uses high angle (e.g., 30 degrees) it should be done in four 90-degree rotations of the wafer in the implant tool to ensure both sides of the channel are doped and that transistors oriented in both X and Y directions.

The Halo implant, together with the well implant, sets the threshold voltage of the transistor. By reducing the initial well implant dose and introducing the Halo implant after gate patterning, a non-uniform channel doping profile is achieved. The Halo implant reduces threshold voltage roll-off in short channel devices. Also, higher drive current is achieved because the transistor has a more abrupt drain-channel junction and higher channel mobility than a non-halo device. Again, the use of molecular ions for these implants creates better abruptness by directly amorphizing the silicon substrate. There is also evidence that the dopant is better activated than without this amorphization, further increasing drive current and device performance.

### Poly Gate Implant

Heavy doping of the polysilicon gate is particularly important in the dual-gate CMOS architecture used in memory devices (DRAM). Due to the high doping concentration, implant times are excessively long (and wafer throughput very low) using traditional monomer ions such as B and P. Typically, the gates are B-doped but in some processes the gate is also counter-doped with high concentrations of P. The use of molecular ions, such as C₄B₁₈Hₓ⁺, C₂B₈H₁₀ and C₂B₁₀Hₓ⁺ can be used for the polygate implants to reduce implant times and restore production-worthy wafer throughput. Deceleration techniques cannot be used for these implants, resulting in very low throughput when conventional boron implants are used. This is because any high energy component of the ion beam will pass through the gate and be implanted in the channel, affecting the threshold voltage of the transistor. Thus, only drift-mode beams can be used. Since dose rate and throughput is high for cluster implants, it significantly enhances throughput for these implants—by a factor of 3 to 5 relative to using monomer boron implants.

Obviously, many modifications and variations of the present invention are possible in light of the above teachings. Thus, it is to be understood that, within the scope of the appended claims, the invention may be practiced otherwise than as specifically described above.

What is claimed and desired to be covered by a Letters Patent is as follows:

1. A method of implanting ions comprising the steps of:
(a) producing a volume of gas phase molecules of carborane defining carborane cluster molecules;
(b) transporting said carborane gas phase molecules to the ionization chamber of an ion source;
(c) ionizing the carborane cluster molecules defining carborane cluster ions; and
(d) accelerating the carborane cluster ions into a semiconductor substrate.

2. The method as recited in claim 1, in which step (a) comprises producing a volume of gas phase molecules of. C₂B₁₀H₁₂.

3. The method as recited in claim 1, in which step (a) comprises producing a volume of gas phase molecules of. C₄B₁₈H₂₂.

4. The method as recited in claim 2, in which step (c) comprises ionizing said molecules of C₂B₁₀H₁₂, to form C₂B₁₀Hₓ⁺ carborane cluster ions.

5. The method as recited in claim 4, in which step (c) comprises ionizing said molecules of C₂B₁₀H₁₂ to form C₂B₁₀H,+carborane cluster ions by direct electron impact ionization.

6. The method as recited in claim 4, in which step (c) comprises ionizing said molecules of C₂B₁₀H₁₂ to form C₂B₁₀Hₓ⁺ carborane cluster ions by arc discharge ionization.

7. The method as recited in claim 3, in which step (c) comprises ionizing said molecules of C₄B₁₈H₂₂, to form C₄B₁₀Hₓ⁺ carborane cluster ions.

8. The method as recited in claim 7, in which step (c) comprises ionizing said molecules of C₄B₁₈H₂₂ to form C₄B₁₈Hₓ⁺ carborane cluster ions by direct electron impact ionization.

9. The method as recited in claim 4, in which step (c) comprises ionizing said molecules of C₄B₁₈H₂₂ to form C₄B₁₈Hₓ⁺ carborane cluster ions by arc discharge ionization.

10. The method as recited in claim 1, in which step (a) comprises producing a volume of gas by sublimation of a solid.

11. The method as recited in claim 1, wherein said step (d) comprises accelerating said carborane cluster ions into a silicon substrate.

12. The method as recited in claim 1, wherein step (d) comprises accelerating said carborane cluster ions into a silicon-on-insulator substrate.

13. The method as recited in claim 1, wherein step (d) comprises accelerating said carborane cluster ions into a strained superlattice substrate.

14. The method as recited in claim 1, wherein step (d) comprises accelerating said carborane cluster ions into a substrate a silicon germanium (SiGe) strained superlaftice substrate.

15. The method of claim 1, wherein step (d) comprises accelerating the carborane cluster ions into a substrate under the influence of a time varying bias applied to the substrate

16. The method of claim 1, wherein step (d) comprises accelerating the carborane cluster ions into a substrate under the influence of a pulsed bias applied to the substrate.

17. The method of claim 1, wherein said step (d) comprises accelerating the carborane cluster ions into a substrate under the influence of a constant bias applied to the substrate.

18. A method of implanting ions into a semiconductor substrate, the method comprising the steps of:
(a) producing a volume of gas phase molecules of carborane cluster molecules;
(b) forming a plasma containing carborane cluster molecules, carborane cluster ions and electrons; and
(c) accelerating the carborane cluster ions into a substrate under the influence of a bias applied to the substrate to implant the carborane cluster ions into a substrate, to perform doping of the substrate.

19. The method of claim 18, wherein step (c) comprises accelerating the carborane cluster ions into a substrate under the influence of a time varying bias applied to the substrate

20. The method of claim 18, wherein step (c) comprises accelerating the carborane cluster ions into a substrate under the influence of a pulsed bias applied to the substrate.

21. The method of claim 18, wherein said step (c) comprises accelerating the carborane cluster ions into a substrate under the influence of a constant bias applied to the substrate.

22. A method for forming a metal oxide semiconductor (MOS) device having a substrate, the method comprising the steps of:
(a) forming a well and opposing trench isolations in a first region of said substrate;
(b) forming a gate stack on said substrate between said opposing trench isolations defining exposed portions of said substrate; said formation comprising the steps of i) depositing or growing a gate dielectric; ii) depositing a polysilicon gate electrode, and iii) patterning to form the gate stack.
(c) depositing a pad oxide onto said exposed portions of said substrate and on top of said gate stack;
(d) implanting carborane ions to form drain extensions between said gate stack and said opposing trench isolations;
(e) forming spacers adjacent said gate stack;
(f) implanting P-type ions, which may be B+, BF2+, carborane, B18Hx+, or B10HX+ ions to form source and drain regions;
(g) providing heat treatment to activate material implanted by said doping step, thereby forming a P-type metal oxide semiconductor (MOS) device (PMOS).

25. The method as recited in claim 24, further including the steps of:
(a) isolating first and second regions on said substrate;
(b) forming said PMOS device in a first region; and
(c) forming an NMOS device in a second region.
